(19) United States
(12) Patent Application Publication
(10) Pub. No.: US 2025/0067350 A1
(43) Pub. Date: Feb. 27, 2025

(54) FLOW DIVIDER AND LIQUID PROCESSING SYSTEM

(71) Applicant: Tokyo Electron Limited, Tokyo (JP)

(72) Inventor: Kaisei Yamashita, Koshi City (JP)

(21) Appl. No.: 18/810,920

(22) Filed: Aug. 21, 2024

(30) Foreign Application Priority Data
Aug. 22, 2023 (JP) 2023-135034

(51) Int. Cl. F16K 11/00; F17D 1/08

(52) U.S. Cl. CPC F16K 11/00; F17D 1/08

(57) ABSTRACT

A flow divider includes a flow divider main body having a guide flow path; an inlet through which a liquid is guided into the guide flow path; and a first outlet and a second outlet through which the liquid is discharged to an outside from the guide flow path. The first outlet is located above the second outlet, and when a bubble exists in the liquid within the guide flow path, a volume of the bubble flowing out to the outside along with the liquid through the second outlet is smaller than a volume of the bubble flowing out to the outside along with the liquid through the first outlet.

### CROSS-REFERENCE TO RELATED APPLICATION

This application claims the benefit of Japanese Patent Application No. 2023-135034 filed on Aug. 22, 2023, the entire disclosure of which is incorporated herein by reference.

### TECHNICAL FIELD

The various aspects and embodiments described herein pertain generally to a flow divider and a liquid processing system.

### BACKGROUND

There is known a system configured to supply a required amount of processing liquid to a processing device from a circulation line while circulating the processing liquid in a tank and the circulation line (see Patent Document 1 and Patent Document 2).
Patent Document 1: Japanese Patent Laid-open Publication No. 2022-003666
Patent Document 2: International Publication No. 2022/009661

### SUMMARY

In an exemplary embodiment, a flow divider includes a flow divider main body having a guide flow path; an inlet through which a liquid is guided into the guide flow path; and a first outlet and a second outlet through which the liquid is discharged to an outside from the guide flow path. The first outlet is located above the second outlet, and when a bubble exists in the liquid within the guide flow path, a volume of the bubble flowing out to the outside along with the liquid through the second outlet is smaller than a volume of the bubble flowing out to the outside along with the liquid through the first outlet.

The foregoing summary is illustrative only and is not intended to be any way limiting. In addition to the illustrative aspects, embodiments, and features described above, further aspects, embodiments, and features will become apparent by reference to the drawings and the following detailed description.

### BRIEF DESCRIPTION OF THE DRAWINGS

In the detailed description that follows, embodiments are described as illustrations only since various changes and modifications will become apparent to those skilled in the art from the following detailed description. The use of the same reference numbers in different figures indicates similar or identical items.

FIG. 1 is a diagram schematically illustrating an example of a liquid processing system;

FIG. 2 is a partial cross sectional view schematically illustrating an example of a processing device;

FIG. 3 is a diagram schematically illustrating a configuration example of a liquid processing system that is not equipped with a flow divider effective for reducing bubbles in a processing liquid, which mainly illustrates a circulation structure for the processing liquid;

FIG. 4A to FIG. 4E are schematic diagrams illustrating an example state of the bubbles in the processing liquid within the circulation line shown in FIG. 3;

FIG. 5 is a diagram schematically illustrating a configuration example of a liquid processing system equipped with a flow divider effective for reducing bubbles in a processing liquid, which mainly illustrates a circulation structure for the processing liquid;

FIG. 6 is a cross sectional view illustrating an example of the flow divider;

FIG. 7A and FIG. 7B are diagrams for describing a gas-liquid separation action of the flow divider (particularly, a guide partition and a shoulder member thereof), which illustrates an example state of the bubbles in the processing liquid near the guide partition and the shoulder member;

FIG. 8A and FIG. 8B are diagrams for describing the gas-liquid separation action of the flow divider (particularly, the guide partition and the shoulder member thereof), which illustrates an example state of the bubbles in the processing liquid near the guide partition and the shoulder member;

FIG. 9A and FIG. 9B are diagrams for describing the gas-liquid separation action of the flow divider (particularly, the guide partition and the shoulder member thereof), which illustrates an example state of the bubbles in the processing liquid near the guide partition and the shoulder member;

FIG. 10A and FIG. 10B are diagrams for describing the gas-liquid separation action of the flow divider (particularly, the guide partition and the shoulder member thereof), which illustrates an example state of the bubbles in the processing liquid near the guide partition and the shoulder member;

FIG. 11 is an enlarged cross sectional view illustrating an example of a flow divider according to a first modification example;

FIG. 12 is a perspective view illustrating another example of the flow divider according to the first modification example, which shows a state where the flow divider is cut in half;

FIG. 13 is an enlarged cross sectional view of an example of a flow divider according to a second modification example;

FIG. 14 is an enlarged cross sectional view of another example of the flow divider according to the second modification example; and

FIG. 15 is a diagram schematically illustrating a configuration example of a liquid processing system according to a third modification example, which mainly illustrates a circulation structure for a processing liquid.

### DETAILED DESCRIPTION

In the following detailed description, reference is made to the accompanying drawings, which form a part of the description. In the drawings, similar symbols typically identify similar components, unless context dictates otherwise. Furthermore, unless otherwise noted, the description of each successive drawing may reference features from one or more of the previous drawings to provide clearer context and a more substantive explanation of the current exemplary embodiment. Still, the exemplary embodiments described in the detailed description, drawings, and claims are not meant to be limiting. Other embodiments may be utilized, and other changes may be made, without departing from the spirit or scope of the subject matter presented herein. It will be readily understood that the aspects of the present disclosure, as generally described herein and illustrated in the drawings, may be arranged, substituted, combined, separated, and designed in a wide variety of different configurations, all of which are explicitly contemplated herein.

Exemplary embodiments of the present disclosure will be described with reference to the accompanying drawings. It should be noted that the drawings are schematic and the shapes and sizes of individual components in the drawings may not necessarily match the actual shapes and sizes of the components, and dimensional relationships between the individual components and relations in sizes of the individual components may sometimes be different from actual values. Even between the drawings, there may exist parts having different dimensional relationships or different ratios.

In the following description, the X direction, Y direction, and Z direction are directions perpendicular to each other. The X and Y directions are horizontal directions, and the Z direction is a height direction (vertical direction) perpendicular to the horizontal directions. Thus, the horizontal directions perpendicular to the height direction (Z direction) is a direction in which an XY plane (horizontal plane) extends.

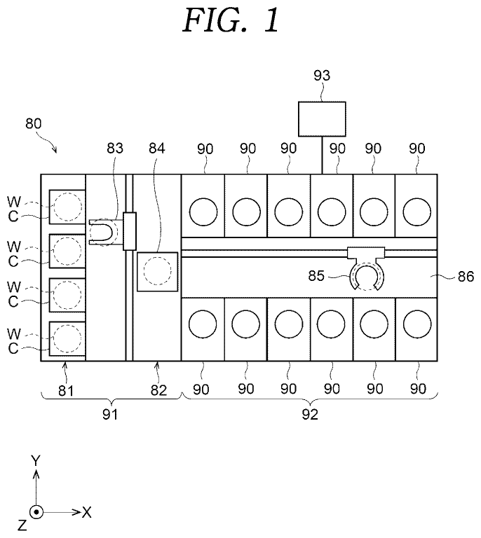

FIG. 1 is a diagram schematically illustrating an example of a liquid processing system 80.

The liquid processing system 80 shown in FIG. 1 has a carry-in/out station 91 and a processing station 92. The carry-in/out station 91 includes a placement section 81 provided with a plurality of carriers C, and a transfer section 82 equipped with a first transfer mechanism 83 and a delivery section 84. Each carrier C accommodates therein a plurality of substrates W horizontally. The substrate W is typically made of a semiconductor wafer, but is not limited thereto. The processing station 92 is equipped with a plurality of processing devices 90 disposed on both sides of a transfer path 86, and a second transfer mechanism 85 configured to be moved back and forth along the transfer path 86.

The substrate W is taken out from the carrier C and loaded in the delivery section 84 by the first transfer mechanism 83, and taken out from the delivery section 84 by the second transfer mechanism 85. Then, the substrate W is carried into the corresponding processing device 90 by the second transfer mechanism 85 to be subjected to a predetermined process in the corresponding processing device 90. Afterwards, the substrate W is taken out from the corresponding processing device 90 and loaded in the delivery section 84 by the second transfer mechanism 85, and then returned back into the carrier C in the placement section 81 by the first transfer mechanism 83. Further, the substrate W may be returned to the carrier C after being processed in two or more processing devices 90.

In the above-described liquid processing system 80, two or more of the plurality of processing devices 90 may have the same configuration or different configurations, and may perform the same process or different processes. Each processing device 90 is capable of performing various types of processes on the substrate W by applying various kinds of processing fluids (for example, processing liquids such as a chemical liquid, a rinse liquid, and a cleaning liquid) to the substrate W. The processing fluid (processing liquid) that can be used in each processing device 90 is not particularly limited, and may contain a component that changes a surface property of the substrate W or may be pure water (DIW (De-Ionized Water)).

The liquid processing system 80 is equipped with a controller 93. The controller 93 is implemented by, for example, a computer, and includes an operation processor and a storage. The storage of the controller 93 stores therein a program and data for various types of processes performed in the liquid processing system 80. The operation processor of the controller 93 appropriately reads and executes the program stored in the storage, thus controlling the various mechanisms of the liquid processing system 80 to perform the various types of processes.

The program and the data stored in the storage of the controller 93 may have been recorded on a computer-readable recording medium, and may be installed from the recording medium into the storage. The computer-readable recording medium may be, by way of non-limiting example, a hard disk (HD), a flexible disk (FD), a compact disk (CD), a magnet optical disk (MO), a memory card, or the like.

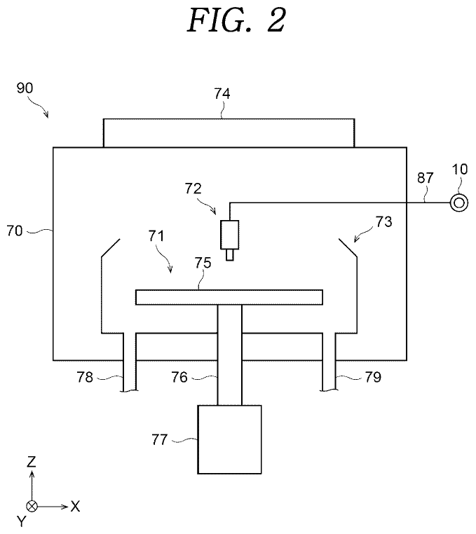

FIG. 2 is a partial cross sectional view schematically illustrating an example of the processing device 90.

The processing device 90 shown in FIG. 2 includes a chamber 70, a substrate holding mechanism 71, a processing liquid supply 72, and a recovery cup 73.

The substrate holding mechanism 71, the processing liquid supply 72, and the recovery cup 73 are disposed inside the chamber 70. A fan filter unit (FFU) 74 is provided at a ceiling portion of the chamber 70 to form a downflow within the chamber 70. The substrate holding mechanism 71 includes a holder 75, a supporting column 76, and a driver 77. The holder 75 is configured to hold the substrate W horizontally. The supporting column 76 extends in a vertical direction. A base end (lower end portion in FIG. 2) of the supporting column 76 is supported by the driver 77, and a leading end (upper end portion in FIG. 2) of the supporting column 76 supports the holder 75 horizontally. The driver 77 is configured to rotate the supporting column 76 (besides, the holder 75 as well) around a vertical axis passing through the center of the supporting column 76 (besides, the holder 75 as well). In this way, as the holder 75 is rotated together with the supporting column 76, the substrate W (see FIG. 1) held by the holder 75 is also rotated.

The processing liquid supply 72 is configured to supply a processing liquid to the substrate W held by the holder 75. The processing liquid supply 72 has a plurality of nozzles, and is connected to a liquid supply system 10. Each nozzle is configured to discharge the processing liquid supplied from the liquid supply system 10 to the substrate W. For example, the plurality of nozzles are configured to respectively correspond to a plurality of types of processing liquids supplied from the liquid supply system 10.

The recovery cup 73 is disposed to surround the holder 75, and serves to collect the processing liquid scattered from the substrate W. A drain port 78 is formed at a bottom of the recovery cup 73, and the processing liquid collected by the recovery cup 73 is drained to the outside of the processing device 90 through the drain port 78. Further, an exhaust port 79 is formed at the bottom of the recovery cup 73, and a gas (downflow) supplied from the FFU 74 is exhausted to the outside of the processing device 90 through the exhaust port 79.

### [Liquid Supply System]

Now, the liquid supply system 10 configured to supply the processing liquid to the processing liquid supply 72 of the processing device 90 will be explained.

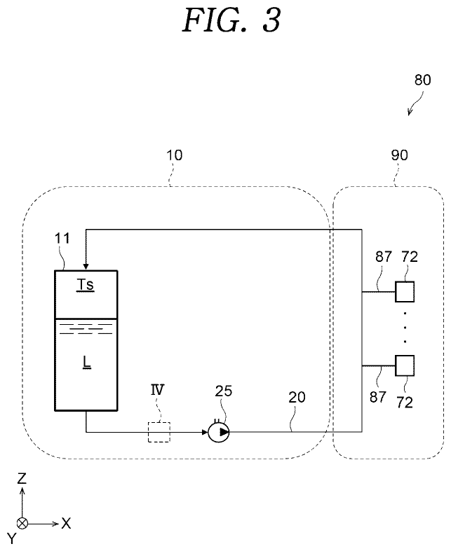

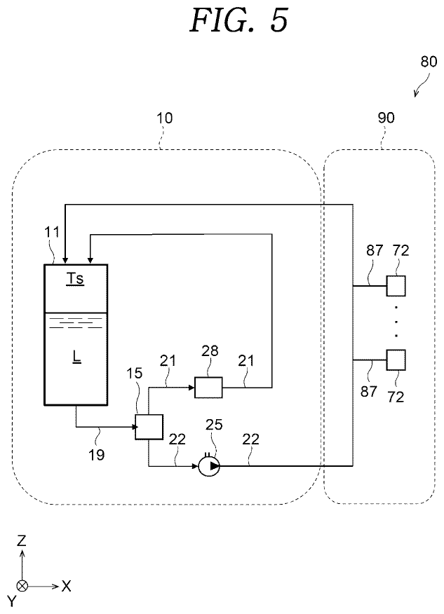

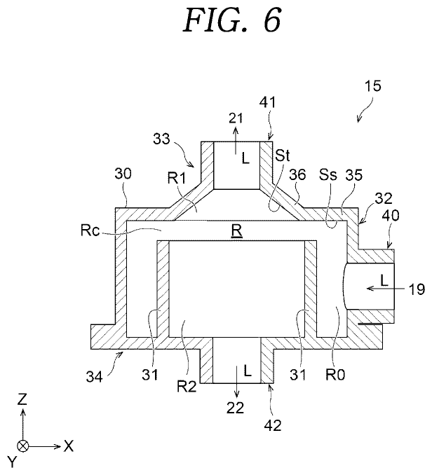

FIG. 3 is a diagram schematically illustrating a configuration example of a liquid processing system 80 without having a flow divider to be described later (see a reference numeral 15 in FIG. 5 and FIG. 6) that is effective in reducing bubbles B in a processing liquid L. FIG. 3 mainly shows a circulation structure of the processing liquid L.

In the liquid processing system 80 shown in FIG. 3, the liquid supply system 10 has a tank 11, and a circulation line 20 connected to the tank 11. The processing liquid L is stored in a storage space Ts of the tank 11. The circulation line 20 is provided with a circulation pump 25 configured to force-feed the processing liquid L. As the circulation pump 25 is driven under the control of the controller 93, the processing liquid L is flown out from the tank 11 through one end of the circulation line 20, and is returned back into the tank 11 through the circulation line 20.

The circulation line 20 is extended to pass through the liquid supply system 10 and the processing device 90. The circulation line 20 in the example shown in FIG. 3 is configured to be shared by the plurality of processing devices 90. A plurality of supply lines 87 branched off from the circulation line 20 are respectively connected to the processing liquid supplies 72 of the plurality of processing devices 90, and the processing liquid L is supplied to each processing liquid supply 72 from the circulation line 20 through the corresponding supply line 87.

FIG. 3 shows the circulation structure for the processing liquid L of a single kind. When multiple kinds of processing liquids are discharged from the respective processing liquid supplies 72, the circulation structure for the processing liquid L as shown in FIG. 3 may be provided for each processing liquid. In this case, circulation lines of the multiple circulation structures are respectively connected to the individual processing liquid supplies 72, and the multiple kinds of processing liquids are respectively supplied to the individual processing liquid supplies 72 from the circulation lines of the multiple circulation structures.

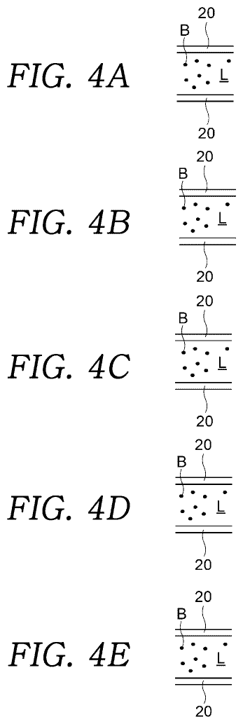

FIG. 4A to FIG. 4E are schematic diagrams showing an example state of the bubbles B in the processing liquid L in the circulation line 20 shown in FIG. 3 (particularly a location between the tank 11 and the circulation pump 25; see a reference sign ‘IV’ in FIG. 3). FIG. 4A to FIG. 4E illustrate example states of the bubbles B in the processing liquid L in the circulation line 20 over time in this order.

As shown in FIG. 4A to FIG. 4E, in the liquid supply system 10 of FIG. 3, which is not provided with a flow divider to be described later functioning as a gas-liquid separation mechanism, the processing liquid L continues to flow out from the tank 11 into the circulation line 20 together with the bubbles B which are contained therein without being reduced. For this reason, as shown in FIG. 4A to FIG. 4E, the number and the total volume of the bubbles B in the processing liquid L in the circulation line 20 do not change significantly with a lapse of time, and, as a result, the bubbles B that has grown in the processing liquid L to have a large diameter may be supplied to the processing device 90.

FIG. 5 is a diagram schematically showing an example configuration of the liquid processing system 80 including a flow divider 15 effective for reducing the bubbles B in the processing liquid L. FIG. 5 mainly shows a circulation structure of the processing liquid L.

The liquid processing system 80 shown in FIG. 5 is equipped with a tank 11, a flow divider 15 connected to the tank 11 via an inlet line 19, and a first circulation line 21 and a second circulation line 22 connected to the flow divider 15 and the tank 11.

The tank 11 is a liquid storage to which the first circulation line 21 and the second circulation line 22 provided in parallel are connected, and is connected to the flow divider 15 (particularly, an ‘inlet’ to be described later; see a reference numeral ‘40’ in FIG. 6A) via the inlet line 19. The tank 11 may be a main tank that is not supplied with the processing liquid L from another tank, or may be a sub-tank/buffer tank that is supplied with the processing liquid L from another tank (main tank or the like).

The processing liquid L is stored in a storage space Ts formed by the internal space of the tank 11. The inlet line 19 is opened to a location (for example, at a bottom) in the storage space Ts where the processing liquid L is stored. On the other hand, the first circulation line 21 and the second circulation line 22 are opened to a space (for example, at a ceiling) above the stored liquid (processed liquid L) in the storage space Ts.

For example, the processing liquid L returned to the tank 11 via the first circulation line 21 and the second circulation line 22 may be returned back into the storage space Ts by flowing along an inner wall surface of the tank 11 that defines the storage space Ts.

A gas is dissolved in the processing liquid L stored in the storage space Ts. Some of the gas in the processing liquid L is released from the processing liquid L while it is stored in the tank 11, but some other may continue to stay in the processing liquid L in the form of bubbles.

The processing liquid L is supplied into the flow divider 15 from the tank 11 through the inlet line 19. When the inlet line 19 has a step-shaped portion or a bent portion, the bubbles in the processing liquid L may grow significantly when the processing liquid L flowing through the inlet line 19 passes through such a step-shaped or bent portion.

The flow divider 15 divides the processing liquid L supplied through the inlet line 19 into the processing liquid L to be sent to the first circulation line 21 and the processing liquid L to be sent to the second circulation line 22.

In particular, the flow divider 15 of the present exemplary embodiment divides the processing liquid L such that the volume of the bubbles B flowing out of the flow divider 15 together with the processing liquid L through the first circulation line 21 becomes greater than the volume of the bubbles B flowing out to the outside together with the processing liquid L through the second circulation line 22.

An example configuration of the flow divider 15 will be described later (see FIG. 6). Briefly, the processing liquid L is guided to an internal flow path (guide flow path) within the flow divider 15 via the inlet, and the processing liquid L flows out from the guide flow path into the first circulation line 21 and the second circulation line 22 via a first outlet and a second outlet, respectively.

The first circulation line 21 is connected to the flow divider 15 (in particular, the ‘first outlet’ to be described later; see a reference numeral ‘41’ in FIG. 6) and the tank 11, and is provided with a liquid sending device 28 provided to send the processing liquid L in the first circulation line 21 from the flow divider 15 to the tank 11. A specific configuration of the liquid sending device 28 is not limited, and it is possible to configure the liquid sending device 28 by, for example, a pump or an ejector.

In the example shown in FIG. 5, all of the processing liquid L flown out from the flow divider 15 into the first circulation line 21 is returned back into the tank 11. However, at least some of the processing liquid L flown into the first circulation line 21 may need to be returned to the tank 11.

The processing liquid L returned to the tank 11 via the first circulation line 21 is discharged from above the processing liquid L stored in the storage space Ts of the tank 11. As a result, the release (defoaming) of the bubbles B from the processing liquid L is promoted, so that the bubbles B in the processing liquid L can be reduced.

The second circulation line 22 is connected to the flow divider 15 (in particular, the ‘second outlet’ to be described later; see a reference numeral ‘42’ in FIG. 6), and is provided with a circulation pump (liquid sending device) 25 configured to send the processing liquid L in the second circulation line 22 downstream.

The second circulation line 22 is extended to pass through the liquid supply system 10 and the processing device 90, and the processing liquid L is supplied form the second circulation line 22 to the processing devices 90 that performs a process by using the processing liquid L. The second circulation line 22 in the present exemplary embodiment is configured to be shared by the plurality of processing devices 90. A plurality of supply lines 87 branched off from the second circulation line 22 are respectively connected to the processing liquid supplies 72 of the plurality of processing devices 90, and the processing liquid L is supplied to each processing liquid supply 72 from the second circulation line 22 through the corresponding supply line 87.

FIG. 5 shows a circulation structure of the processing liquid L of a single kind. When multiple kinds of processing liquids are discharged from the respective processing liquid supplies 72, the circulation structure for the corresponding processing liquid L as shown in FIG. 5 may be provided for each processing liquid. In this case, circulation lines of the multiple circulation structures are respectively connected to the individual processing liquid supplies 72, and the multiple kinds of processing liquids are respectively supplied to the individual processing liquid supplies 72 from the circulation lines of the multiple circulation structures.

In the processing liquid L flown out from the flow divider 15 into the second circulation line 22, at least some of the processing liquid L that has not been supplied to the processing liquid supply 72 of the processing device 90 is returned to the tank 11 via the second circulation line 22.

According to the above-described liquid processing system 80 shown in FIG. 5, the flow divider 15 enables the processing liquid L with the reduced bubbles B to be supplied into the second circulation line 22 that leads to the processing device 90.

Meanwhile, the processing liquid L with the enhanced bubbles B is sent by the flow divider 15 into the first circulation line 21 that is not connected to the processing device 90, and is finally returned back into the tank 11. At least some of the dissolved gas in the processing liquid L returned to the tank 11 via the first circulation line 21 is released into an upper space within the storage space Ts under the pressure release in the tank 11. The dissolved gas in the processing liquid L is reduced in the tank 11 in this way, and the processing liquid L with the reduced dissolved gas is sent back to the flow divider 15 through the inlet line 19.

### [Flow Divider 15]

Now, the flow divider 15 belonging to the liquid supply system 10 will be explained.

FIG. 6 is a cross-sectional view showing an example of the flow divider 15.

The flow divider 15 shown in FIG. 6 includes a flow divider main body 30 having a guide flow path R, an inlet 40 through which the processing liquid L is guided to the guide flow path R, and the first outlet 41 and the second outlet 42 through which the processing liquid L is discharged from the guide flow path R to the outside. The first outlet 41 is located above the second outlet 42.

The guide flow path R includes an inflow guideway R0 through which the processing liquid L from the inlet 40 is introduced, a first outflow guideway R1 located between the inflow guideway R0 and the first outlet 41, and a second outflow guideway R2 located between the inflow guideway R0 and the second outlet 42.

The inflow guideway R0 extends in a height direction (Z direction; a first direction). The first outflow guideway R1 and the second outflow guideway R2 are located deviated from the inflow guideway R0 in a horizontal direction (a second direction) perpendicular to the height direction. The processing liquid L is guided in the height direction (particularly, an upward direction) in the inflow guideway R0, and is then guided in the horizontal direction to be introduced into the first outflow guideway R1 or the second outflow guideway R2.

In the example illustrated in FIG. 6, the inlet 40 is connected to the inflow guideway R0 of the guide flow path R at a sidewall 32 of the flow divider main body 30, and defines a direction of the flow of the processing liquid L supplied from the inlet line 19 so that the processing liquid L is discharged into the inflow guideway R0 toward a guide partition 31. The first outlet 41 is connected to the first outflow guideway R1 including a top portion of the guide flow path R at a ceiling wall 33 of the flow divider main body 30. The second outlet 42 is connected to the second outflow guideway R2 including a bottom of the guide flow path R at a bottom wall 34 of the flow divider main body 30.

The flow divider main body 30 has the guide partition 31, a shoulder member 35, and a tapered member 36.

The guide partition 31 extends in the height direction (Z direction) and partitions at least a part of the inflow guideway R0.

The guide partition 31 shown in FIG. 6 extends from the bottom wall 34 toward the ceiling wall 33, and forms, between the ceiling wall 33 and the guide partition 31, a connection guideway Rc through which the processing liquid L can flow. At least a part of the inflow guideway R0 is formed by a space outside the guide partition 31 in the guide flow path R. Meanwhile, at least a part of the second outflow guideway R2 is formed by a space inside the guide partition 31 in the guide flow path R.

Further, at least a part of the first outflow guideway R1 (including at least a part of a space formed by the tapered member 36) is formed by a space in the guide flow path R facing the space inside the guide partition 31 in an upward direction (a direction from the bottom wall 34 toward the ceiling wall 33).

In this way, at least a part of the inflow guideway R0 and at least a part of the second outflow guideway R2 are separated with the guide partition 31 therebetween. The guide partition 31 shown in FIG. 6 has an annular shape in a plan view seen from above, and the portion of the inflow guideway R0 and the portion of the second outflow guideway R2 separated by the guide partition 31 are arranged concentrically.

The shoulder member 35 defines a part of the inflow guideway R0, and forms a shoulder surface Ss extending in a direction perpendicular to the height direction (that is, a horizontal direction). The tapered member 36 defines at least a part of the first outflow guideway R1, and forms a tapered surface St whose diameter (that is, a size in the horizontal direction) gradually decreases toward the first outlet 41. The shoulder surface Ss and the tapered surface St are connected to each other. Although the shoulder surface Ss and the tapered surface St are directly connected to each other in the example shown in FIG. 6, they may be indirectly connected via another surface (not shown).

In addition, the processing liquid L may be guided to be directed toward the first outlet 41 in a swirling flow in at least a part of the first outflow guideway R1 (for example, in the portion defined by the tapered surface St). This swirling flow of the processing liquid L can be created in any of various ways. By way of example, by studying the structure of the guide flow path R (for example, the structure of the inflow guideway R0 and the first outflow guideway R1) or the shape and the state of the surface forming the first outflow guideway R1, it is possible to create the swirling flow of the processing liquid L in the portion of the first outflow guideway R1 formed by the tapered surface St.

In the flow divider 15 having the above-described configuration, the portion of the second outflow guideway R2 defined by the guide partition 31 has a cross sectional area in the horizontal direction larger than that of the portion of the inflow guideway R0 defined by the guide partition 31. For this reason, a downward movement speed (descending speed) of the processing liquid L in the second outflow guideway R2 is slower than an upward movement speed (ascending speed) of the processing liquid L in the inflow guideway R0. As a result, it is possible to effectively suppress the bubbles B, which are buoyant in the upward direction in the processing liquid L, from flowing out into the second circulation line 22 via the second outflow guideway R2.

Further, in order to suppress the flow of the bubbles B into the second circulation line 22 via the second outflow guideway R2, it is desirable that the descending speed of the processing liquid L in the second outflow guideway R2 is as slow as possible. On the other hand, equal to or more than a required amount of the processing liquid L (for example, equal to or more than a flow rate of the processing liquid L required to be supplied to one or more processing devices 90 connected to the second circulation line 22) needs to be flown out from the second outflow guideway R2 into the second circulation line 22.

Furthermore, the bubbles B having a large diameter have a higher tendency to generate particles than the bubbles B having a small diameter. For this reason, in order to suppress the increase of the particles, it is effective to suppress the large-diameter bubbles B from flowing out into the second circulation line 22 through the second outflow guideway R2. By effectively suppressing the bubbles B from flowing out to the second circulation line 22 through the second outflow guideway R2 to be introduced into the circulation pump (liquid sending device) 25, the increase of the particles can be effectively suppressed.

In addition, as the diameter of the bubble B increases, the buoyant force on the bubble B increases, making it difficult for the bubble B to descend and flow out to the second circulation line 22 through the second outflow guideway R2.

Considering these comprehensively, in order to suppress the bubbles B with the diameter of about 5 mm or more from flowing out to the second circulation line 22 through the second outflow guideway R2, the processing liquid L may be made to flow downwards at a speed lower than, e.g., 0.0006 m/sec in the second outflow guideway R2.

According to the flow divider 15 of FIG. 6 described above, when the bubbles B are present in the processing liquid L in the guide flow path R, the volume of the bubbles B flowing out to the outside along with the processing liquid L through the second outlet 42 is smaller than the volume of the bubbles B flowing out to the outside along with the processing liquid L through the first outlet 41. In addition, the number of the bubbles B flowing out to the outside along with the processing liquid L through the second outlet 42 tends to be smaller than the number of the bubbles B flowing out to the outside along with the processing liquid L through the first outlet 41.

In this way, the flow divider 15 guides some of the processing liquid L, which is supplied from the tank 11 through the inlet line 19, into the second circulation line 22 through the second outlet 42 in the state that the amount of the bubbles contained therein is reduced. Therefore, an operation of the circulation pump 25 provided in the second circulation line 22 can be effectively suppressed from being disturbed by the bubbles B, so that the operation stability of the circulation pump 25 is improved. Furthermore, since the processing liquid L with the reduced bubbles B is supplied to each processing device 90 to which the processing liquid L is supplied from the second circulation line 22, the generation of particles is suppressed, so that a high-quality process can be performed by using the processing liquid L.

Moreover, a flow rate of the processing liquid L flowing out from the guide flow path R to the outside (first circulation line 21) via the first outlet 41 may be set to be smaller than a flow rate of the processing liquid L flowing out from the guide flow path R to the outside (second circulation line 22) through the second outlet 42. In this case, it is possible to effectively suppress the bubbles B in the processing liquid L from being introduced into the second circulation line 22 through the second outlet 42.

Additionally, in the flow divider 15, by allowing the processing liquid L to flow strongly toward the guide partition 31 and the shoulder member 35, the flow of the processing liquid L is disturbed, so that the gas (bubbles B) can be effectively separated from the processing liquid L.

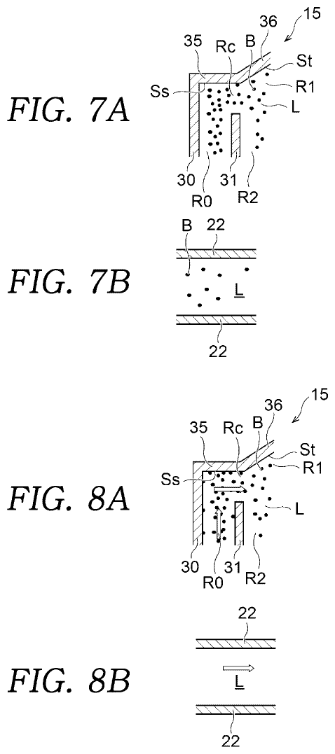

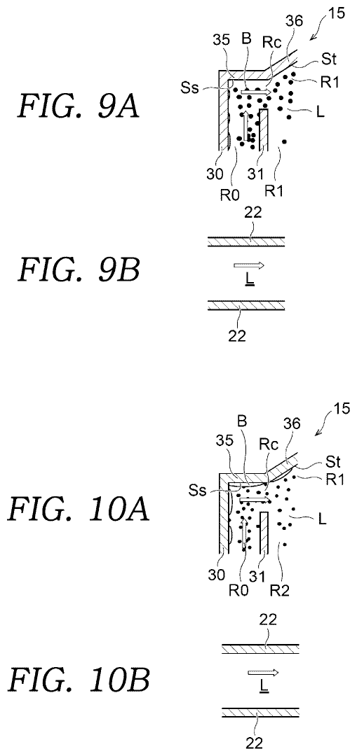

FIG. 7A to FIG. 10B are diagrams illustrating a gas-liquid separation action of the flow divider 15 (particularly, the guide partition 31 and the shoulder member 35), and illustrate an example of the state of the bubbles B in the processing liquid L near the guide partition 31 and the shoulder member 35 over time in this order. FIG. 7A, FIG. 8A, FIG. 9A, and FIG. 10A are enlarged cross sectional views of the flow divider 15 shown in FIG. 6, and FIG. 7B, FIG. 8B, FIG. 9B, and FIG. 10B are enlarged cross sectional view of the second circulation line 22 (particularly, a portion between the flow divider 15 and the circulation pump 25) (see FIG. 5).

FIG. 7A and FIG. 7B illustrate a state in which the processing liquid L is filled in the flow divider 15 and the second circulation line 22, but does not flow downstream and remains stagnant. As shown in FIG. 7A and FIG. 7B, while the processing liquid L is not flowing, the processing liquid L in the flow divider 15 uniformly contains the bubbles B, and the processing liquid L in the second circulation line 22 may also uniformly contain the bubbles B.

FIG. 8A to FIG. 10B show a state in which the processing liquid L filled in the flow divider 15 and the second circulation line 22 is flowing downstream. As depicted in FIG. 8A, the processing liquid L in the flow divider 15 flows downstream while uniformly containing the bubbles B having a relatively small diameter. Then, as the processing liquid L in the flow divider 15 continues to flow downstream, the bubbles B in the processing liquid L gradually combine with each other and grow to have a large volume, as shown in FIG. 9A and FIG. 10A.

Such growth of the bubbles B is highly likely to proceed under a situation where the flow of the processing liquid L is disturbed so the contact between the bubbles B is promoted. Thus, the binding and the growth may be accelerated near the guide partition 31 and the shoulder member 35.

In particular, the bubbles B having a relatively large size and receiving a relatively large buoyant force tend to stay on the shoulder surface Ss extending in the horizontal direction. The bubbles B remaining on the shoulder surface Ss grow further and have a large size due to collision and binding of additional bubbles B in a subsequent process. The bubbles B, which have grown large to some extent on the shoulder surface Ss, are moved from the shoulder surface Ss by the processing liquid L flowing downstream in a subsequent process, and are then moved downstream through the connection guideway Rc.

Since the bubbles B moving downstream in this way receive a large buoyant force according to their size (volume), they tend to easily move toward the first outlet 41 through the first outflow guideway R1 located above.

In particular, in the flow divider 15 shown in FIG. 6 to FIG. 10B, the tapered surface St extends in an obliquely upward direction from an end of the shoulder surface Ss. With this configuration, the bubbles B can be smoothly moved from the shoulder surface Ss to the tapered surface St, and are guided toward the first outlet 41 by the tapered surface St. Thus, the outflow of the bubbles B from the first circulation line 21 is accelerated. As a result, it is possible to more effectively suppress the bubbles B from flowing out to the second circulation line 22 via the second outflow guideway R2 and the second outlet 42 (see FIG. 8B to FIG. 10B).

### First Modification Example

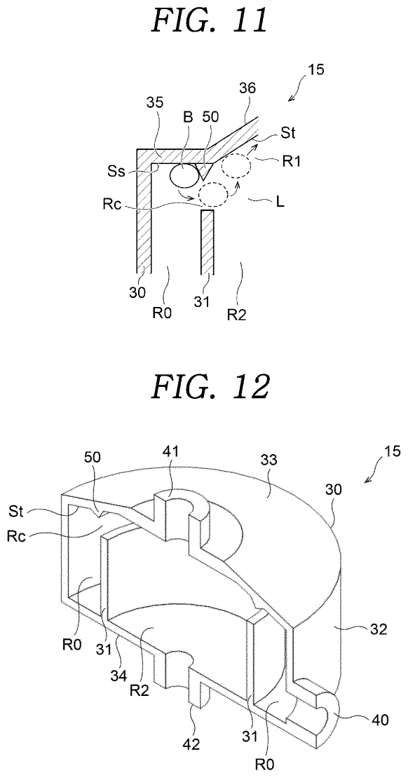

FIG. 11 presents an enlarged cross sectional view of an example of the flow divider 15 according to a first modification example. In FIG. 11, parts identical or corresponding to those of the flow divider 15 shown in FIG. 6 to FIG. 10B described above will be assigned same reference numerals, and detailed description thereof will be omitted.

The flow divider main body 30 may have a protrusion 50 that protrudes downwards from an inner wall of the flow divider main body 30 that defines at least one of the inflow guideway R0 and the first outflow guideway R1.

In the example shown in FIG. 11, at the shoulder member 35 of the flow divider main body 30, the protrusion 50 having a triangular cross section is provided at a position facing the guide partition 31 in the height direction (Z direction). By providing such a protrusion 50, it is possible to promote the staying and the growth of the bubbles B in the processing liquid L, which is advantageous in causing a stronger buoyant force to act on the bubbles B.

The bubbles B, which have grown to a certain extent on the shoulder surface Ss, are moved from the shoulder surface Ss so as to pass through the connection guideway Rc and go beyond the protrusion 50 by the subsequent processing liquid L flowing downstream, as shown by a dotted line in FIG. 11. Then, the bubbles B are moved downstream.

Further, the protrusion 50 is not limited to the example shown in FIG. 11.

FIG. 12 is a perspective view showing another example of the flow divider 15 according to the first modification example, and shows the flow divider 15 cut in half.

The protrusion 50 does not necessarily need to face the guide partition 31 in the height direction (Z direction). For example, as in the example shown in FIG. 12, the protrusion 50 may be provided at a position distanced farther from the first outlet 41 than the guide partition 31 in the horizontal direction. Alternatively, the protrusion 50 may be provided at a position closer to the first outlet 41 than the guide partition 31 is in the horizontal direction.

Additionally, the protrusion 50 may be provided on the tapered surface St that defines at least a part of the inflow guideway R0 and/or the first outflow guideway R1.

In addition, the protrusion 50 may have a cross-sectional shape other than the triangle, may have a symmetrical or asymmetrical cross-sectional shape.

### Second Modification Example

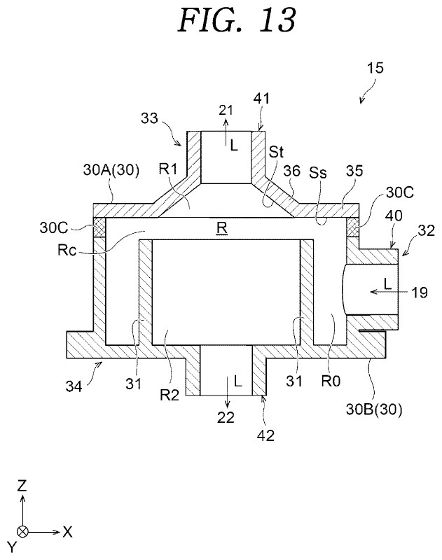

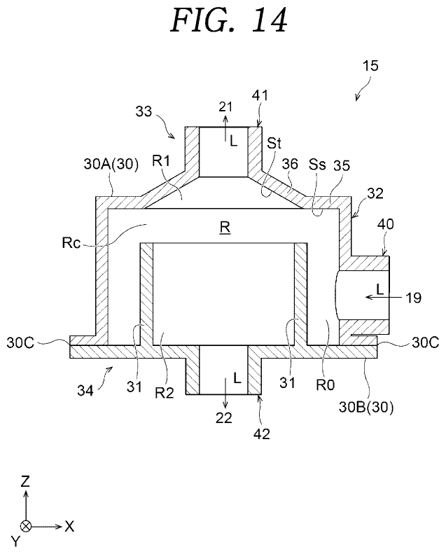

FIG. 13 presents an enlarged cross sectional view of an example of the flow divider 15 according to a second modification example. FIG. 14 provides an enlarged cross sectional view of another example of the flow divider 15 according to the second modification example. In FIG. 13 and FIG. 14, parts identical or corresponding to those of the flow divider 15 shown in FIG. 6 to FIG. 10B described above will be assigned the same reference numerals, and detailed description thereof will be omitted.

The flow divider main body 30 may have a first divided main body 30A and a second divided main body 30B configured to be detachably attached to each other.

As an example, as shown in FIG. 13, the ceiling wall 33 of the flow divider main body 30 may be configured to be separated from the sidewall 32 and the bottom wall 34. Alternatively, as shown in FIG. 14, the bottom wall 34 of the flow divider main body 30 may be configured to be separated from the sidewall 32 and the ceiling wall 33.

A main body connector 30C configured to detachably fix the first divided main body 30A and the second divided main body 30B to each other is not particularly limited. Such a main body connector 30C may be, by way of example, a fastening member having a threaded portion, or may be a fastening member using concave-convex fitting other than the screw. The main body connector 30C may be configured as a part of the first divided main body 30A and the second divided main body 30B, and may include a member separated from the first divided main body 30A and the second divided main body 30B.

Further, the flow divider main body 30 may include three or more divided main bodies that are configured to be detachably attached to each other.

As in this modification example, as the flow divider main body 30 of the flow divider 15 has a detachable structure, maintenance of the flow divider 15 can be easily performed. For example, an inner wall surface of the flow divider main body 30 can be easily cleaned, or the divided main bodies can be replaced in a convenient way.

Further, it is possible to change properties of constituent materials or the like for each divided main body. By way of example, only a divided main body including the ceiling wall 33 (the first divided main body 30A in FIG. 13 and FIG. 14) may be made of a transparent material (for example, transparent resin or quartz). In this case, while allowing the sidewall 32 and/or the bottom wall 34 to have a structure (constituent material or the like) featuring excellent strength, it is possible to visually check the state of the bubbles B in the guide flow path R within the flow divider main body 30 through the ceiling wall 33.

In addition, it may be also possible to prepare multiple types of divided main bodies with different structures for a specific divided main body, and to select and use an optimal type of divided main body according to a situation in which it is used. By way of example, for a divided main body including the bottom wall 34 (the second divided main body 30B in FIG. 13 and FIG. 14), multiple divided main bodies with different cross-sectional area/volume ratios of the inflow guideway R0 and the second outflow guideway R2, which are defined by the guide partition 31, in the horizontal direction may be prepared. In this case, depending on the situation, it is possible to select and use a divided main body with optimal cross-sectional area/volume ratios.

### Third Modification Example

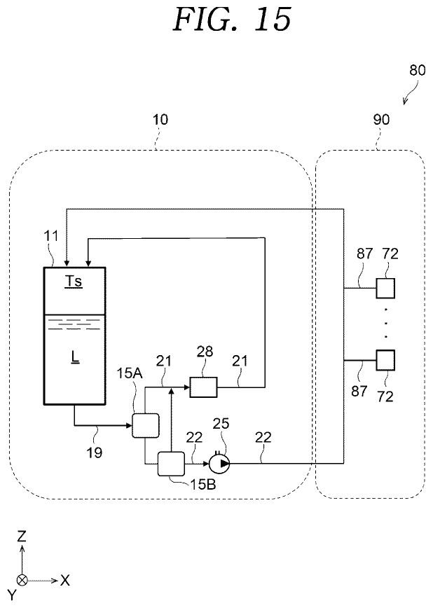

FIG. 15 is a diagram schematically illustrating an example configuration of the liquid processing system 80 according to a third modification example, which mainly illustrates a circulation structure of the processing liquid L. In FIG. 15, parts identical or corresponding to those of the liquid processing system 80 shown in FIG. 5 described above will be assigned the same reference numerals, and detailed description thereof will be omitted.

In a single circulation structure, there may be provided a plurality of flow dividers 15 configured to allow the processing liquid L with the reduced bubbles B to flow out to the second circulation line 22 via the second outlet 42.

In the example shown in FIG. 15, a first flow divider 15A and a second flow divider 15B are provided in series.

The inlet line 19 is connected to the first flow divider 15A, and the first flow divider 15A serves to send the processing liquid L supplied from the tank 11 via the inlet line 19 into the first circulation line 21 and the second circulation line 22.

The second flow divider 15B is provided at a location between the first flow divider 15A and the circulation pump 25 in the second circulation line 22, and serves to send the processing liquid L supplied from a location upstream of the second circulation line 22 into the first circulation line 21 and the second circulation line 22 (particularly, a downstream side thereof).

Each of the first flow divider 15A and the second flow divider 15B may have the same configuration as the above-described flow divider 15 (see FIG. 6 to FIG. 14). That is, in the first and second flow dividers 15A and 15B, the volume of the bubbles B flowing into the second circulation line 22 along with the processing liquid L through the second outlet 42 is smaller than the volume of the bubbles B flowing into the first circulation line 21 along with the processing liquid L through the first outlet 41.

As illustrated in FIG. 15, by providing the plurality of flow dividers 15A and 15B, the processing liquid L in which the bubbles B are more effectively reduced can be supplied to the processing liquid supply 72 of each processing device 90.

### Other Modification Examples

A specific configuration of the guide flow path R in the flow divider 15 (the first flow divider 15A and the second flow divider 15B) is not particularly limited. In the above-described example (FIG. 6, etc.), at least a part of the first outflow guideway R1 is defined by the tapered surface St. However, at least a part of the inflow guideway R0 and/or the second outflow guideway R2 may be defined by the tapered surface.

It will be appreciated that the disclosure in the present specification is illustrative in all aspects and is not intended to be limiting. In the above-described exemplary embodiments and modification examples, various omissions, replacement and modifications may be made without departing from the scope and spirit of the claims. For example, the above-described exemplary embodiments and modification examples may be combined in whole or in part, and exemplary embodiments other than those described above may be combined with the above-described exemplary embodiments or modification examples. In addition, the effects of the present disclosure described in this specification are merely examples, and other effects may result.

Furthermore, a technical category for embodying the above-described technical concept is not particularly limited. By way of example, the above-described technical concept may be embodied by a computer-executable program for executing one or multiple sequences (processes) included in a method of manufacturing or using the above-described apparatus on a computer. Further, the above-described technical concept may be embodied by a computer-readable non-transitory recording medium in which such a computer-executable program is stored.

According to the exemplary embodiment, it is possible to provide the technique advantageous for sending the liquid, which may contain the bubbles, while reducing the bubbles.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting. The scope of the inventive concept is defined by the following claims and their equivalents rather than by the detailed description of the exemplary embodiments. It shall be understood that all modifications and embodiments conceived from the meaning and scope of the claims and their equivalents are included in the scope of the inventive concept.

We claim:

1. A flow divider, comprising:
a flow divider main body having a guide flow path;
an inlet through which a liquid is guided into the guide flow path; and
a first outlet and a second outlet through which the liquid is discharged to an outside from the guide flow path,
wherein the first outlet is located above the second outlet, and when a bubble exists in the liquid within the guide flow path, a volume of the bubble flowing out to the outside along with the liquid through the second outlet is smaller than a volume of the bubble flowing out to the outside along with the liquid through the first outlet.

2. The flow divider of claim 1,
wherein the guide flow path comprises an inflow guideway into which the liquid from the inlet is introduced, a first outflow guideway located between the inflow guideway and the first outlet, and a second outflow guideway located between the inflow guideway and the second outlet,
the flow divider main body comprises a guide partition configured to partition at least a part of the inflow guideway, and
the inlet discharges the liquid into the inflow guideway toward the guide partition.

3. The flow divider of claim 2,
wherein the inflow guideway extends in a first direction,
the first outflow guideway and the second outflow guideway are located deviated from the inflow guideway in a second direction perpendicular to the first direction, and
the liquid is guided in the second direction after being guided in the first direction in the inflow guideway.

4. The flow divider of claim 1,
wherein the guide flow path comprises an inflow guideway into which the liquid from the inlet is introduced, a first outflow guideway located between the inflow guideway and the first outlet, and a second outflow guideway located between the inflow guideway and the second outlet,
the flow divider main body comprises a guide partition extending in a first direction,
at least a part of the inflow guideway and at least a part of the second outflow guideway are separated from each other with the guide partition therebetween, and
a portion of the second outflow guideway defined by the guide partition is larger than a portion of the inflow guideway defined by the guide partition in a cross sectional area in a direction perpendicular to the first direction.

5. The flow divider of claim 1,
wherein the guide flow path comprises an inflow guideway into which the liquid from the inlet is introduced, a first outflow guideway located between the inflow guideway and the first outlet, and a second outflow guideway located between the inflow guideway and the second outlet,
the flow divider main body comprises:
a guide partition extending in a first direction, and defining at least a part of the inflow guideway;
a shoulder member defining a part of the inflow guideway, and forming a shoulder surface extending in a direction perpendicular to the first direction; and
a tapered member defining at least a part of the first outflow guideway, and forming a tapered surface whose diameter gradually decreases toward the first outlet, and
the shoulder surface and the tapered surface are directly or indirectly connected.

6. The flow divider of claim 1,
wherein the guide flow path comprises an inflow guideway into which the liquid from the inlet is introduced, a first outflow guideway located between the inflow guideway and the first outlet, and a second outflow guideway located between the inflow guideway and the second outlet, and
the liquid heads toward the first outlet in a swirling flow in at least a part of the first outflow guideway.

7. The flow divider of claim 1,
wherein the inlet is connected to an inflow guideway of the guide flow path at a sidewall of the flow divider main body,
the first outlet is connected to a first outflow guideway including a top portion of the guide flow path at a ceiling wall of the flow divider main body,
the second outlet is connected to a second outflow guideway including a bottom portion of the guide flow path at a bottom wall of the flow divider main body,
the flow divider main body comprises a guide partition extending from the bottom wall toward the ceiling wall, a connection guideway through which the liquid flows being formed between the guide partition and the ceiling wall,
at least a part of the inflow guideway is formed by a space of the guide flow path outside the guide partition,
at least a part of the second outflow guideway is formed by a space of the guide flow path inside the guide partition, and
at least a part of the first outflow guideway is formed by a space of the guide flow path that faces the space inside the guide partition in a direction from the bottom wall toward the ceiling wall.

8. The flow divider of claim 1,
wherein a flow rate of the liquid flowing out to the outside from the guide flow path through the first outlet is less than a flow rate of the liquid flowing out to the outside from the guide flow path through the second outlet.

9. The flow divider of claim 1,
wherein the guide flow path comprises an inflow guideway into which the liquid from the inlet is introduced, a first outflow guideway located between the inflow guideway and the first outlet, and a second outflow guideway located between the inflow guideway and the second outlet, and
the flow divider main body comprises a protrusion protruding downwards from an inner wall surface of the flow divider main body that defines at least one of the inflow guideway or the first outflow guideway.

10. The flow divider of claim 1,
wherein the flow divider main body comprises a first divided main body and a second divided main body configured to be detachably attached to each other.

11. A liquid processing system, comprising:
a flow divider as claimed in claim 1 in which a processing liquid is guided into the guide flow path through the inlet and is flown out from the guide flow path through the first outlet and the second outlet;
a first outlet line connected to the first outlet; and
a second outlet line connected to the second outlet,
wherein the processing liquid is supplied from the second outlet line into a processor configured to perform a process with the processing liquid.

12. The liquid processing system of claim 11, further comprising:
a liquid storage to which the first outlet line and the second outlet line are connected, and connected to the inlet via an inlet line,
wherein the processing liquid is supplied from the liquid storage to the flow divider through the inlet line,
at least some of the processing liquid flown out from the flow divider into the first outlet line is returned back to the liquid storage, and
at least some of the processing liquid flown out from the flow divider into the second outlet line that has not been supplied to the processor is returned back to the liquid storage.

13. The liquid processing system of claim 12,
wherein the processing liquid returned back to the liquid storage through the first outlet line is discharged from above the processing liquid stored in a storage space of the liquid storage.

14. The liquid processing system of claim 11,
wherein the flow divider is plural in number.
